(19) United States
(12) Patent Application Publication
(10) Pub. No.: US 2025/0266327 A1
(43) Pub. Date: Aug. 21, 2025

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Hee Jun Jang, Chungcheongbuk-do (KR); Wang Gu Lee, Seoul (KR); Gam Han Yong, Incheon (KR)

(21) Appl. No.: 18/583,744

(22) Filed: Feb. 21, 2024

(51) Int. Cl. H01L 23/49; H01L 23/00; H01L 23/28; H01L 23/48; H01L 23/538; H01L 25/00; H01L 25/065

(52) U.S. Cl. CPC H01L 23/49; H01L 23/28; H01L 23/481; H01L 23/5385; H01L 25/0652; H01L 25/50; H01L 24/16; H01L 24/32; H01L 24/73; H01L 2224/16227; H01L 2224/32225; H01L 2224/73204

(57) ABSTRACT

A method of manufacturing an electronic device includes providing vertical interconnects over a first carrier and bonding an inorganic layer of a routing component to an inorganic layer of the first carrier. The method also includes encapsulating the vertical interconnects and the routing component in a lower encapsulant and providing an upper substrate such that a conductive structure of the upper substrate is coupled to the vertical interconnects and to an upper side of the routing component. The method further includes coupling a first electronic component and a second electronic component to the upper substrate and providing a second carrier over the first electronic component and the second electronic component. The method may also include removing the first carrier and providing a lower substrate such that a conductive structure of the lower substrate is coupled to the vertical interconnects. Other methods and related electronic devices are also disclosed.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIG. 1A shows an enlarged view of region A of the example electronic device of FIG. 1.

FIG. 1B shows an enlarged view of region A of the example electronic device of FIG. 1 with an alternative routing component.

FIGS. 2A-2L show cross-sectional views of an example method for manufacturing an example electronic device.

FIGS. 3A-3D show cross-sectional views of an example method for manufacturing an example routing component.

FIG. 4 shows a cross-sectional view of the example electronic device of FIG. 1 with a lid.

### DESCRIPTION

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” “third,” etc. may be used herein to describe various elements. These terms are only used to distinguish one element from another. The elements described using “first,” “second,” etc. should not be limited by these terms. For example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A may be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” may refer to a mechanical and/or electrical coupling.

An example method of manufacturing an electronic device may include providing vertical interconnects over an upper side of a first carrier, and bonding a routing component inorganic layer on a lower side of a routing component to an inorganic layer on the upper side of the first carrier. The method may also include encapsulating the vertical interconnects and the routing component in a lower encapsulant, and providing an upper substrate to an upper side of the lower encapsulant such that a conductive structure of the upper substrate is coupled to upper sides of the vertical interconnects and to an upper side of the routing component. Further, the method may include coupling a first electronic component and a second electronic component to an upper side of the upper substrate, and providing a second carrier over the first electronic component and the second electronic component. The method may further include removing the first carrier from the routing component and the vertical interconnects, and providing a lower substrate to a lower side of the lower encapsulant such that a conductive structure of the lower substrate is coupled to lower sides of the vertical interconnects.

Another example method of manufacturing an electronic device may include providing a lower substrate comprising an upper side and a lower side, and providing a routing component on the upper side of the lower substrate. The routing component may comprise a routing component die, a routing component redistribution structure on an upper side of the routing component die, and a routing component inorganic layer along a lower side of the routing component die. A lower side of the routing component inorganic layer may contact the upper side of the lower substrate. The method may also include providing vertical interconnects on the upper side of the lower substrate, and providing a lower encapsulant that encapsulates the vertical interconnects and the routing component. Further, the method may include providing an upper substrate over the lower encapsulant such that a lower side of the upper substrate is coupled to an upper side of the routing component redistribution structure, and providing a first electronic component and a second electronic component coupled to an upper side of the upper substrate such that the first electronic component is electrically coupled to the second electronic component via the upper substrate and the routing component redistribution structure.

An example electronic device may include a lower substrate comprising an upper side and a lower side, and an upper substrate comprising an upper side and a lower side. The electronic device may also include vertical interconnects that couple the upper side of the lower substrate to the lower side of the upper substrate, and a routing component comprising a routing component die, a routing component redistribution structure on an upper side of the routing component die, and a routing component inorganic layer along a lower side of the routing component die. An upper side of the routing component redistribution structure may be coupled to the lower side of the upper substrate. A lower side of the routing component inorganic layer may contact the upper side of the lower substrate. The electronic device may further include a lower encapsulant that encapsulates the routing component and the vertical interconnects, a first electronic component coupled to the upper side of the upper substrate, and a second electronic component coupled to the upper side of the upper substrate. The second electronic component may be electrically coupled to the first electronic component via the upper substrate and the routing component redistribution structure.

Other examples are included in the present disclosure. Such examples may be found in the figures, in the claims, or in the description of the present disclosure.

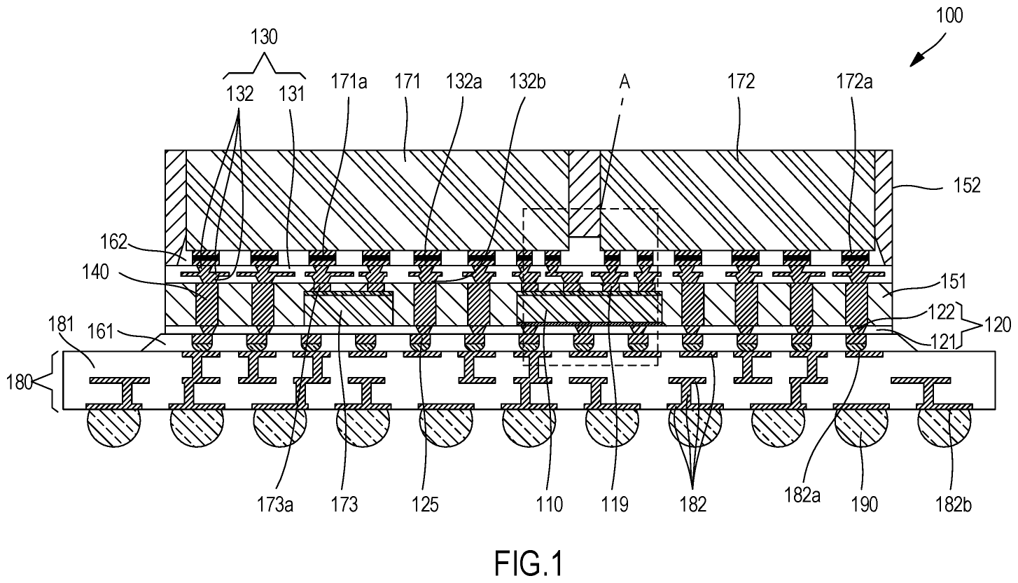

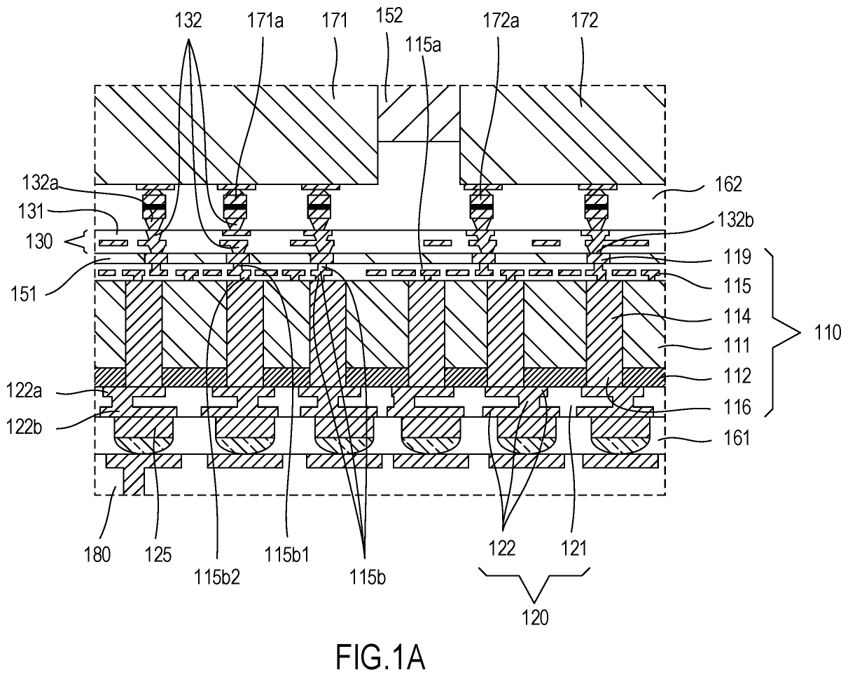

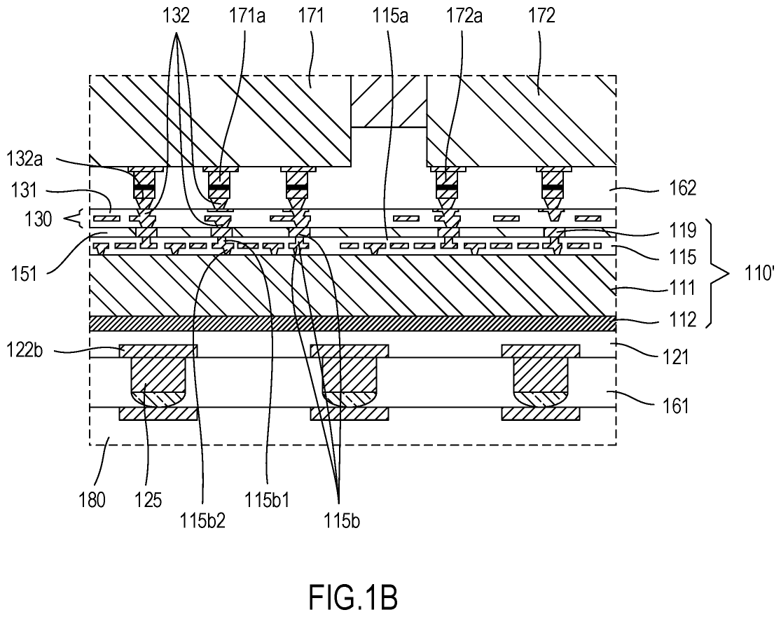

FIG. 1 shows a cross-sectional view of an example electronic device 100. FIG. 1A is an enlarged view of electronic device 100 from region A in FIG. 1. In the example shown in FIGS. 1 and 1A, the electronic device 100 may comprise a routing component 110, a lower substrate 120, lower substrate interconnect structures 125, an upper substrate 130, vertical interconnects 140, a lower encapsulant 151, an upper encapsulant 152, a first electronic component 171, and a second electronic component 172. In some examples, the electronic device 100 may comprise a base substrate 180, a first underfill 161 between the lower substrate and the base substrate 180, and the base substrate external interconnects 190. In some examples, the electronic device 100 may comprise a second underfill 162 between upper substrate 130 and the first electronic component 171 and/or the second electronic component 172.

The lower substrate 120 may comprise a lower substrate dielectric structure 121 and a lower substrate conductive structure 122. The lower substrate conductive structure 122 may comprise lower substrate upper terminals 122a (FIG. 1A) and lower substrate lower terminals 122b (FIG. 1A).

The upper substrate 130 may comprise an upper substrate dielectric structure 131 and an upper substrate conductive structure 132. The upper substrate conductive structure 132 may comprise upper substrate upper terminals 132a and upper substrate lower terminals 132b.

The base substrate 180 may comprise a base substrate dielectric structure 181 and a base substrate conductive structure 182. The base substrate conductive structure 182 may comprise base substrate upper terminals 182a and base substrate lower terminals 182b. The lower substrate interconnect structures 125 may couple the lower substrate lower terminals 122b to the base substrate upper terminals 182a.

The first electronic component 171 may comprise first electronic component interconnects 171a and the second electronic component 172 may comprise second electronic component interconnects 172a. The first electronic component interconnects 171a and the second electronic component interconnects 172a may be coupled to the upper substrate upper terminals 132a. In some examples, the electronic device 100 may include a third electronic component 173. The third electronic component 173 may comprise third electronic component interconnects 173a. The third electronic component interconnects 173a may be coupled to the upper substrate lower terminals 132b.

With continuing reference to FIG. 1A, the routing component 110 may comprise a routing component die 111, a routing component inorganic layer 112, routing component through-interconnects 114, a routing component redistribution structure 115, routing component lower interconnects 116, and routing component upper interconnects 119. The routing component redistribution structure 115 may comprise a redistribution structure dielectric structure 115a and a redistribution structure conductive structure 115b. The redistribution structure conductive structure 115b may comprise redistribution structure upper terminals 115b1 and redistribution structure lower terminals 115b2. The redistribution structure lower terminals 115b2 may be coupled to the routing component through-interconnects 114. The redistribution structure upper terminals 115b1 may be coupled to the routing component upper interconnects 119. The routing component upper interconnects 119 may couple the upper substrate conductive structure 132 to redistribution structure conductive structure 115b.

FIG. 1B shows an enlarged cross-sectional view of region A of an electronic device 100 that comprises a routing component 110′ in place of the routing component 110 of FIG. 1A. In accordance with various examples, the routing component 110′ may comprise routing component die 111, a routing component inorganic layer 112, a routing component redistribution structure 115, and routing component upper interconnects 119. The routing component 110′ may be similar to routing component 110. For example, the routing component 110′ may be similar to the routing component 110 in terms of the routing component die 111, the routing component inorganic layer 112, and the routing component redistribution structure 115. However, in this example, the routing component 110′ does not comprise the routing component through-interconnects 114 and/or routing component lower interconnects 116 of the routing component 110.

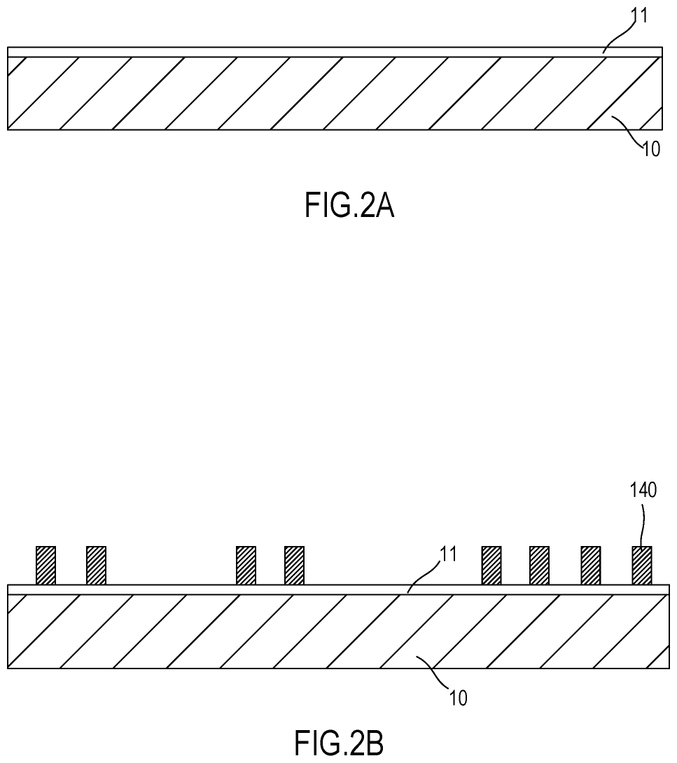

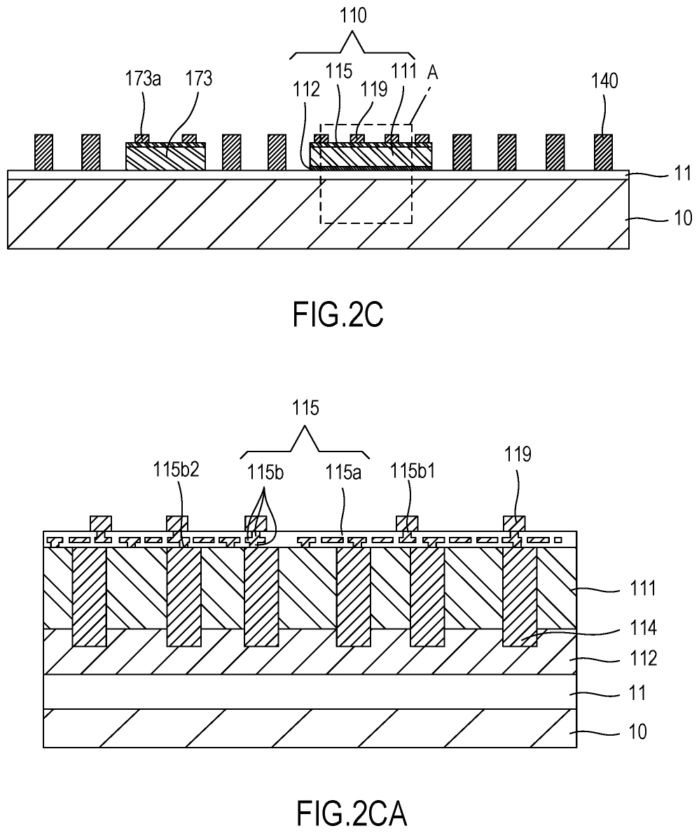

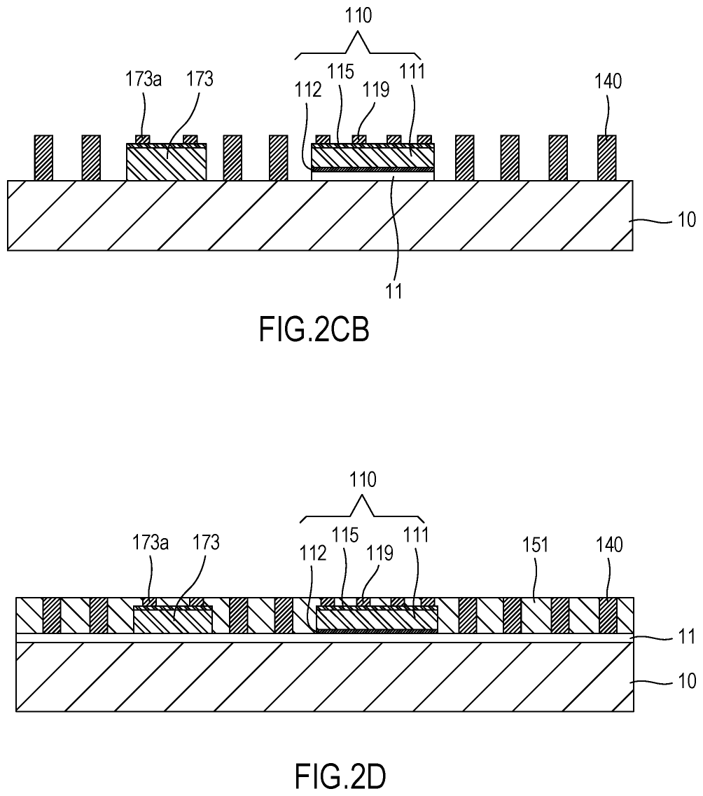

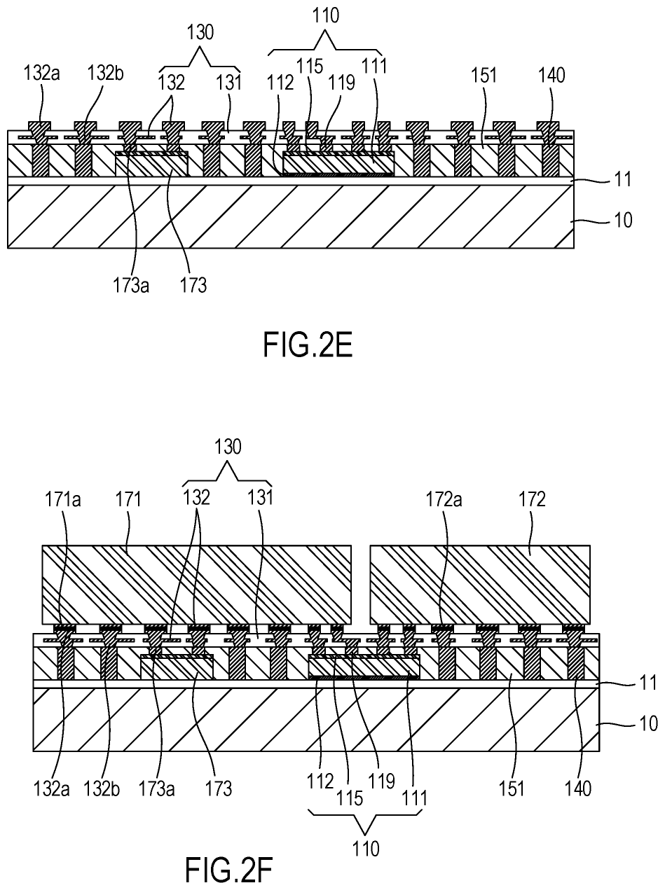

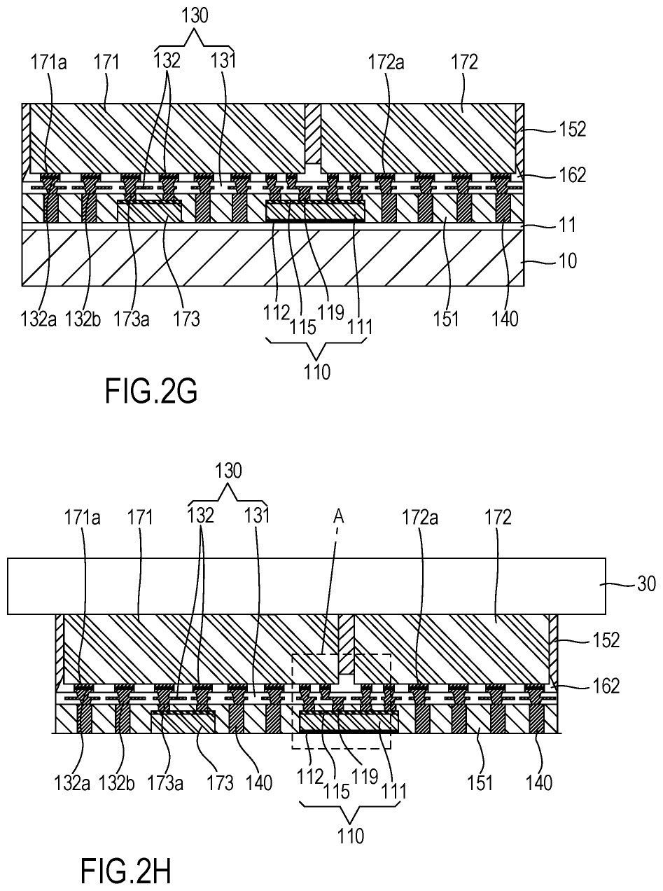

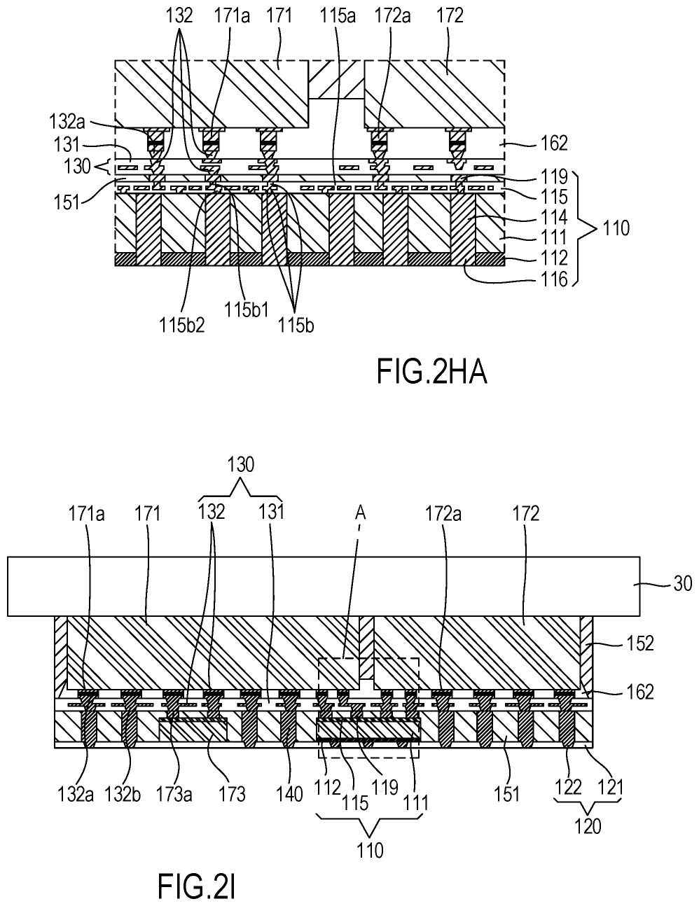

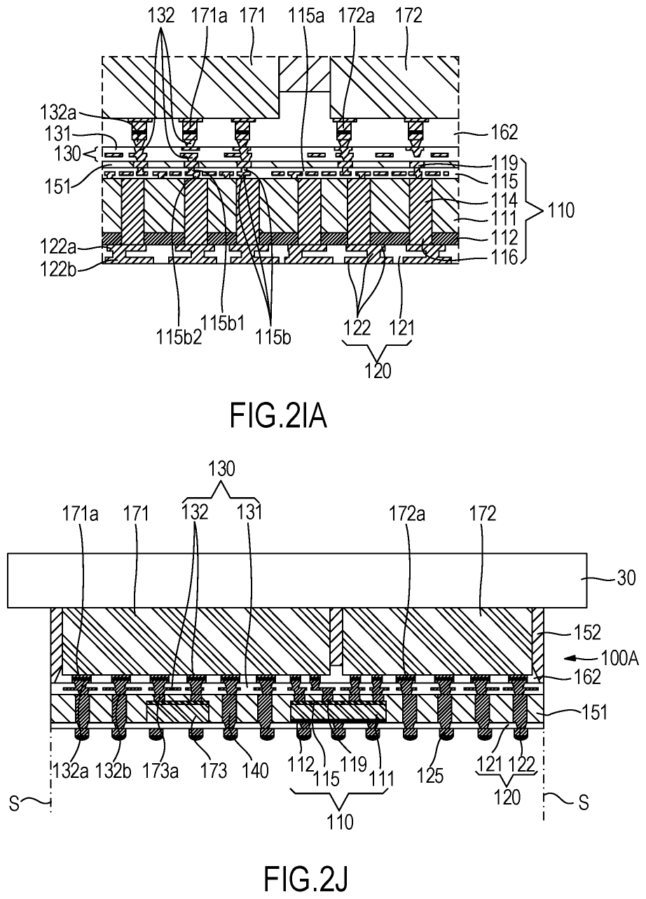

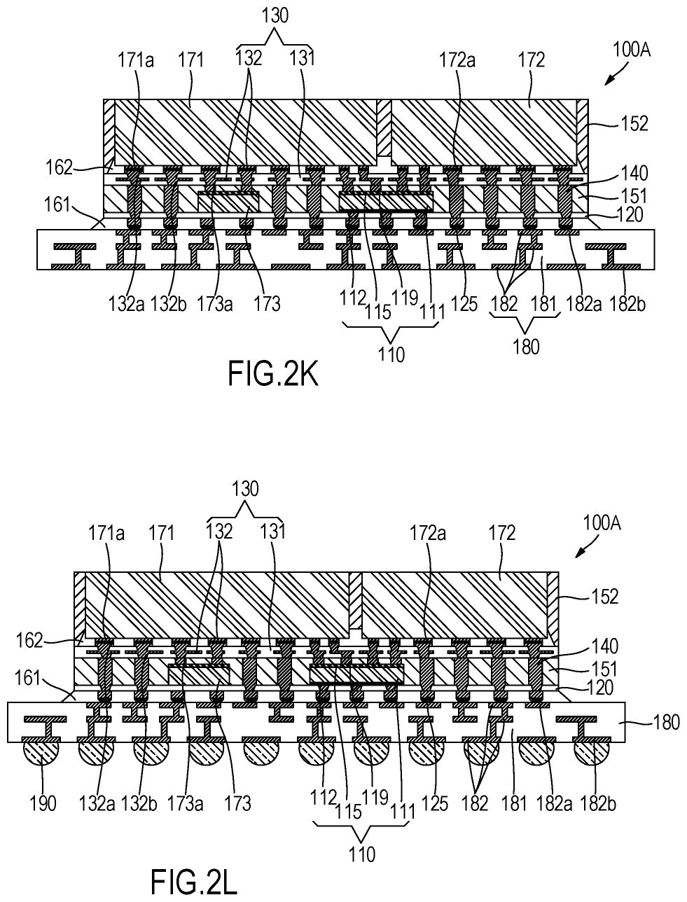

FIGS. 2A to 2L show cross-sectional views of an example method for manufacturing an example electronic device 100. FIG. 2A shows a cross section view of the electronic device 100 at an early stage of manufacture. In the example shown in FIG. 2A, an upper side of a first carrier 10 may be provided or covered with an inorganic layer 11.

The first carrier 10 may comprise or be referred to as a plate, a board, a wafer, a panel, or a strip. In some examples, the first carrier 10 may be a wafer. The thickness of the first carrier 10 may range from approximately 100 micrometers (μm) to approximately 1000 μm, and the width or diameter of the first carrier 10 may range from approximately 100 millimeters (mm) to approximately 300 mm. The first carrier 10 may be made of glass or silicon. The first carrier 10 may enable handling of multiple components during a process of providing the routing component 110, the lower substrate 120, the vertical interconnects 140, the lower encapsulant 151, the upper encapsulant 152, the first electronic component 171, the second electronic component 172, and the third electronic component 173. For example, multiple electronic devices 100 may be simultaneous formed over the first carrier 10.

The inorganic layer 11 may cover an upper side of the first carrier 10. In some examples, the inorganic layer 11 may comprise silicon oxide layer (SiO2), silicon carbon nitride (SiCN), and/or a silicon nitride layer (SiN). In some examples, the inorganic layer 11 may be provided on the upper side of the first carrier 10 by deposition or coating. For example, the inorganic layer 11 may comprise a substrate passivation layer of the first carrier 10 provided by deposition such as physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). For example, the inorganic layer 11 may comprise a substrate passivation of the first carrier 10 provided by coating such as spin coating, spray coating, dip coating, or rod coating. The thickness of inorganic layer 11 may range from approximately 0.05 μm to approximately 20 μm, 0.1 μm to 10 μm, or 0.5 μm to 1.0 μm.

FIG. 2B shows a cross section view of the electronic device 100 at a later stage of manufacture. In the example shown in FIG. 2B, the vertical interconnects 140 may be provided over the upper side of the inorganic layer 11. The vertical interconnects 140 may comprise or be referred to as pillars, posts, through mold vias (TMVs), ball-type structures such as copper core solder balls (CCBs), copper cube columns (CCCs), or wires. The vertical interconnects 140 may be provided by electroplating, electroless plating, sputtering, PVD, CVD, MOCVD, ALD, LPCVD, PECVD, and/or ball drop. The vertical interconnects 140 may comprise copper (Cu), aluminum (Al), nickel (Ni), palladium (Pd), titanium (Ti), tungsten (W), titanium/tungsten, gold (Au), silver (Ag), an alloy, and/or other suitably conductive material as known to one of ordinary skill in the art. In some examples, the vertical interconnects 140 may be formed by providing a seed layer over the inorganic layer 11, forming a patterned mask (e.g., a photo resist) over the seed layer, and forming, for example, via plating, the vertical interconnects 140 in openings in the patterned mask where the seed layer is exposed. After providing the vertical interconnects 140, the portions of the patterned mask not covered by the vertical interconnects 140 may be removed. In some examples, the height of the vertical interconnects 140 may range from approximately 0.5 μm to approximately 800 μm. In some examples, each of the width and pitch of the vertical interconnects 140 may range from approximately 0.5 μm to approximately 200 μm.

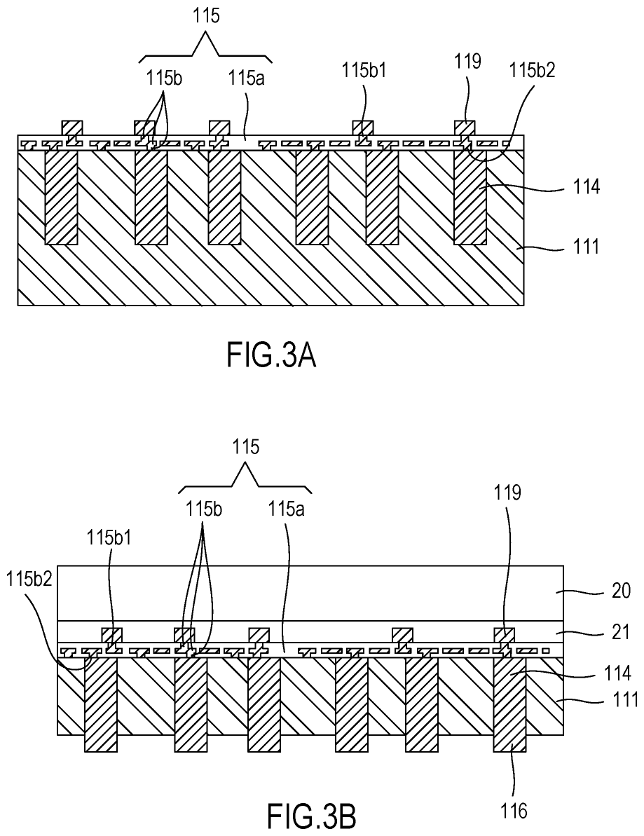

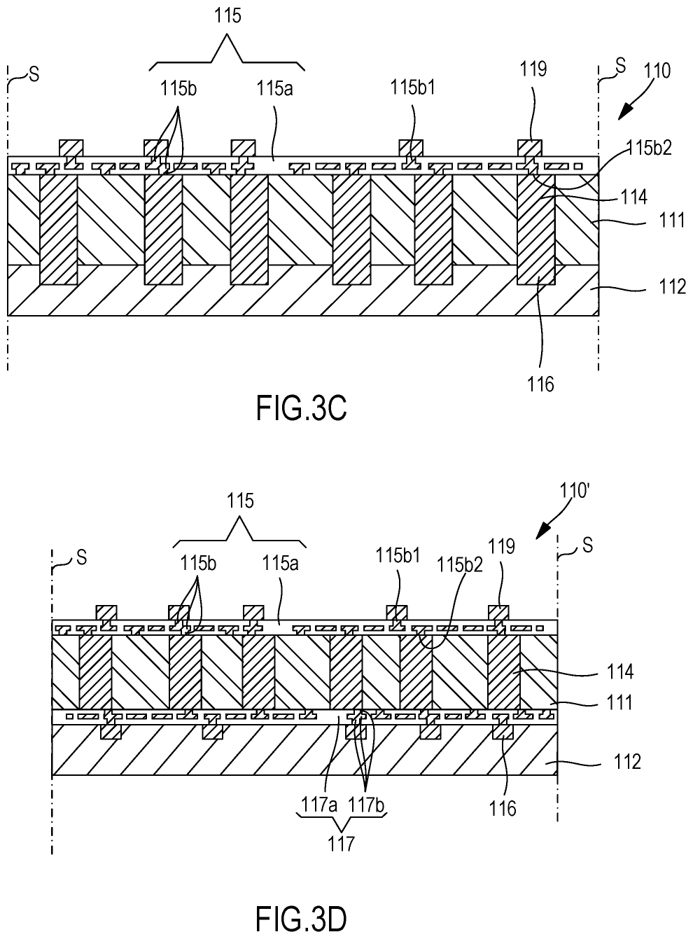

FIG. 2C shows a cross section view of the electronic device 100 at a later stage of manufacture. FIG. 2CA is an enlarged view of the electronic device 100 at region A in FIG. 2C. In FIG. 2C, the routing component 110 may be provided on the upper side of the inorganic layer 11. Turning now to FIGS. 3A to 3C, cross-sectional views of an exemplary method for manufacturing routing component 110 are shown. While FIGS. 3A-3C show a single routing component 110, it is contemplated and understood that the routing component 110 may be part of and/or manufactured from a wafer that includes multiple routing components 110.

FIG. 3A shows a cross-sectional view of the routing component 110 at an early stage of manufacture. In accordance with various examples, the routing component 110 may include the routing component die 111. In some examples, the routing component die 111 comprises wafer material (e.g., Si or other semiconductor material). The routing component die 111 may include the routing component through-interconnects 114 provided in an upper side of the routing component die 111. In some examples, the routing component through-interconnects 114 are provided in blind vias and/or extend only partially through routing component die 111, such that a portion of routing component die 111 remains between the routing component through-interconnects 114 and a lower side of the routing component die 111. In some examples, each of the pitch and width of the routing component through-interconnects 114 may range from approximately 0.5 μm to approximately 200 μm.

The routing component 110 may further include the routing component redistribution structure 115. The routing component redistribution structure 115 may be provided over and/or covering the upper side of the routing component die 111 and the routing component through-interconnects 114. The routing component redistribution structure 115 may comprise the redistribution structure dielectric structure 115a and the redistribution structure conductive structure 115b. In some examples, the routing component redistribution structure 115 may be formed during a back-end-of-line (BEOL) process.

The redistribution structure dielectric structure 115a may comprise one or more dielectric layers made of a dielectric or insulating material interleaved between conductive layers of the redistribution structure conductive structure 115b. In some examples, the redistribution structure dielectric structure 115a may comprise one or more layers of inorganic dielectric material such as SiO2, SiCN, Si3N4. In some examples, the redistribution structure dielectric structure 115a may include one or more layers of organic dielectric material such as polyimide (PI), polymer, benzocyclobutene (BCB), polybenzoxazole (PBO), bismaleimide triazine (BT), Ajinomoto Buildup Film (ABF) or resin. The redistribution structure dielectric structure 115a may be provided by spin coating, spray coating, dip coating, rod coating, printing, oxidation, PVD, CVD, ALD, LPCVD, PECVD, and/or any other process known to one of ordinary skill in the art. In some examples, the thickness of redistribution structure dielectric structure 115a may range from approximately 0.05 μm to approximately 50 μm. The thickness of redistribution structure dielectric structure 115a may refer to individual layers of redistribution structure dielectric structure 115a.

The redistribution structure conductive structure 115b may comprise one or more conductive layers defining signal distribution elements (e.g., traces, vias, pads, conductive paths, and/or UBMs) that are interleaved with dielectric layers of redistribution structure dielectric structure 115a. The redistribution structure conductive structures 115b may comprise or be referred to as traces, pads, vias, conductive paths, wire patterns, circuit patterns, redistribution layers (RDLs), and/or UBM. In some examples, the redistribution structure conductive structures 115b may comprise copper, aluminum, iron, nickel, gold, silver, palladium, titanium, and/or tin. The redistribution structure conductive structures 115b may be provided by electrolytic plating, electroless plating, sputtering, deposition such as PVD, CVD, MOCVD, ALD, LPCVD, or PECVD. The redistribution structure conductive structure 115b may distribute electrical signals in a vertical direction and a lateral direction through the routing component redistribution structure 115. In some examples, the thickness of the redistribution structure conductive structure 115b may range from approximately 0.5 μm to approximately 20 μm. The thickness of the redistribution structure conductive structure 115b may refer to the individual conductive layers of the redistribution structure conductive structure 115b.

In accordance with various examples, the routing component upper interconnects 119 are provided over the redistribution structure conductive structure 115b. For example, the routing component upper interconnects 119 may be provided on the redistribution structure upper terminals 115b1. In some examples, the thickness of routing component upper interconnects 119 may range from approximately 0.1 μm to approximately 20 μm, and each of the width and the pitch of the routing component upper interconnects 119 may range from approximately 0.1 μm to approximately 200 μm.

The redistribution structure conductive structure 115b may be coupled to routing component through-interconnects 114 and to the routing component upper interconnects 119. For example, the redistribution structure upper terminals 115b1 of the redistribution structure conductive structure 115b may be coupled to the routing component upper interconnects 119 on the upper side of the routing component redistribution structure 115. The redistribution structure lower terminals 115b2 of the redistribution structure conductive structure 115b may be coupled to routing component through-interconnects 114. The redistribution structure conductive structure 115b may electrically couple one or more of the routing component upper interconnects 119 to one or more of the routing component through-interconnects 114. In accordance with various examples, at least some of the routing component upper interconnects 119 are not electrically coupled to the routing component through-interconnects 114 and instead provide electrical connection between the first electronic component 171 and the second electronic component 172, with momentary reference to FIG. 1.

FIG. 3B shows a cross-sectional view of the routing component 110 at a later stage of manufacture. In the example shown in FIG. 3B, a second carrier 20 is provided over and/or covering the routing component redistribution structure 115 and the routing component upper interconnects 119. The second carrier 20 may comprise a substantially planar plate, board, wafer, panel, or strip. The second carrier 20 may comprise metal, ceramic, glass, or semiconductor material (e.g., Si).

The second carrier 20 may be coupled to the routing component redistribution structure 115 and the routing component upper interconnects 119. The second carrier 20 may comprise a temporary bond layer 21. The temporary bond layer 21 may contact and be coupled to the routing component redistribution structure 115 and the routing component upper interconnects 119. The temporary bond layer 21 may cover the routing component redistribution structure 115 and the routing component upper interconnects 119. In some examples, the temporary bond layer 21 may comprise a temporary adhesive film, a temporary adhesive tape, and/or a temporary adhesive coating. For example, the temporary bond layer 21 may comprise a thermal release tape (or film) or an optical release tape (or film), where the adhesive strength of temporary bond layer 21 is weakened or removed by heat or light, respectively. In some examples, the adhesive strength of the temporary bond layer 21 may be weakened or removed by physical force and/or chemical force. The temporary bond layer 21 may permit separation of the routing component 110 from the second carrier 20 when the manufacturing process of the routing component 110 is generally completed.

After coupling the second carrier 20 to the routing component 110, the lower side of the routing component die 111 may be removed. The lower side of the routing component die 111 may be removed by grinding, etching, laser ablation, and/or any other suitable removal process. In some examples, the lower side of the routing component die 111 may be removed first by grinding to expose the lower side of respective routing component through-interconnects 114 and then etching to cause the lower side of respective routing component through-interconnects 114 to protrude from the lower side of the routing component die 111. In some examples, after removing the lower portion of routing component die 111, the thickness of routing component die 111 may range from approximately 0.5 μm to approximately 300 μm. A length of the protruding portion of the routing component through-interconnects 114 may range from approximately 0 μm to approximately 1 μm. The routing component through-interconnects 114 may be configured to provide signal transmission between the upper side and the lower side of the routing component die 111. In some examples, the protruding portions of the routing component through-interconnects 114 may comprise or be referred to as routing component lower interconnects 116. In some examples, the routing component through-interconnects 114 may be coplanar with the lower side of the routing component die 111.

As shown in FIG. 3D, the routing component through-interconnects 114 in some examples may be coplanar with a routing component lower redistribution structure 117. The routing component lower redistribution structure 117 may comprise a redistribution structure dielectric structure 117a and a redistribution structure conductive structure 117b. The redistribution structure dielectric structure 117a and the redistribution structure conductive structure 117b of the routing component redistribution structure 117 may be formed over the lower side of the routing component die 111 in a manner similar to the redistribution structure dielectric structure 115a and the redistribution structure conductive structure 115b of the routing component redistribution structure 115. The redistribution structure conductive structure 117b may be coupled to the lower side of the routing component through-interconnects 114. Routing component lower interconnects 116 (e.g., bumps, pillars, studs, etc.) may formed along the lower side of the routing component lower redistribution structure 117 and coupled to the redistribution structure conductive structure 117b.

FIG. 3C shows a cross section view of the routing component 110 at a later stage of manufacture. In the example shown in FIG. 3C, the routing component inorganic layer 112 may be provided over and covering the lower side of the routing component die 111 and the lower side of the routing component lower interconnects 116 (e.g., the protruding lower portions of the routing component through-interconnects 114). The routing component inorganic layer 112 may be provided by spin coating, spray coating, dip coating, rod coating, printing, oxidation, PVD, CVD, ALD, LPCVD, PECVD, and/or any other process known to one of ordinary skill in the art. In some examples, after deposition, the lower side of the routing component inorganic layer 112 may be planarized through a planarization process (e.g., via chemical mechanical planarization (CMP)). In some examples, the routing component inorganic layer 112 may comprise an oxide layer and/or nitride layer. For example, the routing component inorganic layer 112 may comprise SiO2, SiCN, and/or SiN. In some examples, the thickness of the routing component inorganic layer 112 may range from approximately 0.5 μm to approximately 50 μm.

In some examples, through the above-described processes, the routing components 110 may be provided in a wafer form. The wafer may then be singulated to provide individual, discrete routing components 110. Singulation may include cutting or sawing along saw streets S and/or through routing component die 111, the routing component inorganic layer 112, and/or the routing component redistribution structure 115. Through the singulation process, the lateral side of the routing component die 111, the lateral side of the routing component inorganic layer 112, and the lateral side of the routing component redistribution structure 115 may be coplanar. The overall thickness of routing component 110 may range from approximately 10 μm to approximately 800 μm, and the area of the routing component 110 may range from approximately 0.5 mm (millimeter)×0.5 mm to approximately 70 mm×70 mm.

Returning now to FIGS. 2C and 2CA, the routing component 110 may be provided on the first carrier 10. In some examples, pick-and-place equipment may pick up the routing component 110 and place the routing component 110 on the upper side of the inorganic layer 11 that covers the upper side of the first carrier 10, such that the routing component inorganic layer 112 contacts the inorganic layer 11. The routing component inorganic layer 112 may then be bonded to the first carrier 10 via its bonding to the inorganic layer 11. In some examples, the bond between the routing component inorganic layer 112 and the inorganic layer 11 may initially start as a Van der Waals bond that progresses to a covalent bond through time and/or temperature. For example, bonding between the routing component inorganic layer 112 and the inorganic layer 11 may be achieved at low temperatures through surface activation prior to bonding. In some examples, surface activation may form hydroxyl (OH) groups on the lower side of the routing component inorganic layer 112 and the upper side of the inorganic layer 11. For example, hydrogen (H) may be generated on the lower side of the routing component inorganic layer 112 and the upper side of the inorganic layer 11 through plasma treatment, oxygen (O) particles separated from water or air during plasma treatment may bind to the hydrogen (H) on the lower side of the routing component inorganic layer 112 and the upper side of the inorganic layer 11, and hydroxyl (OH) groups may be induced on the lower side of the routing component inorganic layer 112 and the upper side of the inorganic layer 11. Bonding between the routing component inorganic layer 112 and the inorganic layer 11 may then be achieved at relatively low temperatures. In some examples, the routing component inorganic layer 112 and the inorganic layer 11 may be bonded to each other at temperatures ranging from approximately 25° C. to approximately 400° C. As used herein to describe temperatures, the term approximately may mean+/−5%, +/−10%, +/−15%, +/−20%, or +/−25%.

While the inorganic layer 11 is shown as covering the entire upper side of the first carrier 10, it is contemplated and understood that, in some examples, the inorganic layer 11 may cover only a part of the first carrier 10. For example, and with reference to FIG. 2CB, in some examples, the location of the inorganic layer 11 may be selected to correspond with the location of the routing component 110. In this regard, the inorganic layer 11 may be a patterned layer. The routing component 110 may be positioned on and bonded to the upper side of patterned inorganic layer 11.

Returning FIG. 2C, in some examples, the third electronic component 173 may be provided on the upper side of the first carrier 10. The lower side of the third electronic component 173 may be coupled to the upper side of the first carrier 10 by an adhesive. In some examples, an inorganic layer, similar to the routing component inorganic layer 112, may be provided on the lower side of the third electronic component 173, and the third electronic component 173 may be coupled to the inorganic layer 11 of the first carrier 10 in manner similar to, or the same as, the routing component 110. The third electronic component 173 may comprise third electronic component interconnects 173a. The third electronic component interconnects 173a may be input/output terminals of the third electronic component 173. In some examples, the third electronic component 173 may comprise or be referred to as an active device, a die, a chip, or a package. In some examples, the third electronic component 173 may be a passive device.

FIG. 2D shows a cross section view of the electronic device 100 at a later stage of manufacture. In the example shown in FIG. 2D, the lower encapsulant 151 may be provided over the first carrier 10, the routing component 110, the vertical interconnects 140, and the third electronic component 173. The lower encapsulant 151 may contact the inorganic layer 11, the routing component 110, the vertical interconnects 140, and/or the third electronic component 173. The routing component upper interconnects 119, the third electronic component interconnects 173a, and the vertical interconnects 140 may be exposed at the upper side of the lower encapsulant 151.

In some examples, the lower encapsulant 151 may comprise or be referred to as a body or molding. The lower encapsulant 151 may comprise an epoxy mold compound, a resin, filler-reinforced polymer, a B-stage pressed film, and may be provided by compression molding, transfer molding, liquid body molding, vacuum lamination, paste printing, film assist molding, or any other suitable deposition process. In some examples, the lower encapsulant 151 may initially cover the upper sides of the routing component upper interconnects 119, the vertical interconnects 140, and the third electronic component interconnects 173a. An upper portion of the lower encapsulant 151 may be removed (e.g., by grinding and/or chemical etching) to expose the upper sides of the routing component upper interconnects 119, the vertical interconnects 140, and the third electronic component interconnects 173a. The upper side of the lower encapsulant 151 may be coplanar with the upper sides of the routing component upper interconnects 119, he vertical interconnects 140, and the third electronic component interconnects 173a. By bonding the routing component inorganic layer 112 to the inorganic layer 11 covering the first carrier 10 movement of the routing component 110 with respect to the first carrier may be minimized or prevented during deposition of the lower encapsulant 151.

FIG. 2E shows a cross-sectional view of the electronic device 100 at a later stage of manufacture. In the example shown in FIG. 2E, the upper substrate 130 may be provided over and/or covering the routing component 110, the vertical interconnects 140, the third electronic component 173, and the lower encapsulant 151.

The upper substrate 130 may comprise the upper substrate dielectric structure 131 and the upper substrate conductive structure 132. The upper substrate conductive structure 132 may comprise the upper substrate upper terminals 132a and the upper substrate lower terminals 132b. In accordance with various examples, the upper substrate dielectric structure 131 may comprise or be referred to as one or more dielectrics, dielectric materials, dielectric layers, passivation layers, insulating layers, or protective layers. In some examples, the upper substrate dielectric structure 131 may comprise organic dielectric materials. For example, the upper substrate dielectric structure 131 may comprise an electrically insulating material such as polymer, PI, BCB, PBO, bismaleimide triazine (BT), or ABF. In some examples, the upper substrate dielectric structure 131 may be provided by spin coating, spray coating, dip coating, rod coating, printing, oxidation, PVD, CVD, MOCVD, ALD, LPCVD, PECVD, or other processes as known to one of ordinary skill in the art. The upper substrate dielectric structure 131 may maintain the shape of the upper substrate upper substrate 130 and may also structurally support the upper substrate conductive structure 132 the first electronic component 171, and the second electronic component 172 (FIG. 2F). The upper substrate dielectric structure 131 may contact and be interleaved with conductive layers and/or other structures of the the upper substrate conductive structure 132. In some examples, the thicknesses of individual dielectric layers of the upper substrate dielectric structure 131 may range from about 3 μm to about 100 μm.

In accordance with various embodiments, the upper substrate conductive structure 132 may comprise or be referred to as one or more conductors, conductive materials, conductive paths, conductive layers, RDLs, wiring layers, signal distribution elements, traces, vias, pads, or UBM. In some examples, one or more conductive layers of the the upper substrate conductive structure 132 may be interleaved with dielectric layers of the upper substrate dielectric structure 131. In some examples, the upper substrate conductive structure 132 may comprise Cu, Al, Ni, Pd, Ti, W, Ti/W, Au, Ag, an alloy, or other suitably conductive material known to one of ordinary skill in the art. In some examples, the upper substrate conductive structure 132 may be provided by sputtering, electroless plating, electrolytic plating, PVD, CVD, MOCVD, ALD, LPCVD, PECVD, or other processes as known to one of ordinary skill in the art. The upper substrate upper terminals 132a may be located at the upper side of the upper substrate dielectric structure 131. The upper substrate lower terminals 132b may be located at the lower side of the upper substrate dielectric structure 131 and may be coupled to the routing component upper interconnects 119, the vertical interconnects 140, and the third electronic component interconnects 173a. In accordance with various examples, the upper substrate dielectric structure 131 and the upper substrate conductive structure 132 may each include any number of layers (i.e., fewer or more layer than the number of layers shown in FIG. 2E). In some examples, the thickness of the upper substrate 130 may range from approximately 0.5 μm to approximately 50 μm.

In some examples, the upper substrate 130 may comprise a redistribution layer (RDL) substrate. The redistribution layer substrate may comprise one or more conductive redistribution layers and one or more dielectric layers and (a) may be formed layer by layer over an electronic device to which the redistribution layer substrate is coupled, or (b) may be formed layer by layer over a carrier, which may be entirely removed or at least partially removed after the electronic device and the redistribution layer substrate are coupled together. The redistribution layer substrate may be manufactured layer by layer as a wafer-level substrate on a round wafer in a wafer-level process, and/or as a panel-level substrate on a rectangular or square panel carrier in a panel-level process. The redistribution layer substrate may be formed in an additive buildup process and may include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns may be formed using a plating process such as, for example, an electroplating process or an electroless plating process. The conductive patterns may comprise a conductive material such as, for example, copper or other plateable metal. The locations of the conductive patterns may be made using a photo-patterning process such as, for example, a photolithography process and a photoresist material to form a photolithographic mask. The dielectric layers of the redistribution layer substrate may be patterned with a photo-patterning process, and may include a photolithographic mask through where light is exposed to photo-pattern desired features such as vias in the dielectric layers. The dielectric layers may be made from photo-definable organic dielectric materials such as, for example, PI, BCB, or PBO. Such dielectric materials may be spun-on or otherwise coated in liquid form, rather than attached as a pre-formed film. To permit proper formation of desired photo-defined features, such photo-definable dielectric materials may omit structural reinforcers or may be filler-free, without strands, weaves, or other particles that could interfere with the light from the photo-patterning process. In some examples, such filler-free characteristics of filler-free dielectric materials may permit a reduction of the thickness of the resulting dielectric layer. Although the photo-definable dielectric materials described above may be organic materials, in some examples the dielectric materials of the RDL substrates may comprise one or more inorganic dielectric layers. Some examples of inorganic dielectric layer(s) may comprise silicon nitride (Si3N4), silicon oxide (SiO2), and/or SiON. The inorganic dielectric layer(s) may be formed by growing the inorganic dielectric layers using an oxidation or nitridization process instead using photo-defined organic dielectric materials. Such inorganic dielectric layers may be filler-fee, without strands, weaves, or other dissimilar inorganic particles. In some examples, the redistribution layer substrate may omit a permanent core structure or carrier such as, for example, a dielectric material comprising bismaleimide triazine (BT) or FR4. This type of redistribution layer substrate may comprise or be referred to as a coreless substrate or a build-up substrate. Other substrates, as disclosed herein, may comprise a redistribution layer substrate.

In some examples, the upper substrate 130 may comprise a pre-formed substrate. The pre-formed substrate may be manufactured prior to attachment to an electronic device and may comprise dielectric layers between respective conductive layers. The conductive layers may comprise copper and may be formed using an electroplating process. The dielectric layers may be relatively thicker non-photo-definable layers and may be attached as a pre-formed film rather than as a liquid and may include a resin with fillers such as strands, weaves, and/or other inorganic particles for rigidity and/or structural support. Since the dielectric layers are non-photo-definable, features such as vias or openings may be formed by using a drill or laser. In some examples, the dielectric layers may comprise a prepreg material or ABF. The pre-formed substrate may include a permanent core structure or carrier such as, for example, a dielectric material comprising bismaleimide triazine (BT) or FR4, and dielectric and conductive layers may be formed on the permanent core structure. In some examples, the pre-formed substrate may be a coreless substrate that omits the permanent core structure, and wherein the dielectric layers and the conductive layers are formed on a sacrificial carrier that is removed after formation of the substrate and before attachment to the electronic device. The pre-formed substrate may be referred to as a printed circuit board (PCB) or a laminate substrate. Such pre-formed substrate may be formed through a semi-additive or modified-semi-additive process. Any of the substrates, as disclosed herein, may comprise pre-formed substrates.

FIG. 2F shows a cross-sectional view of electronic device 100 at a later stage of manufacture. In the example shown in FIG. 2F, the first electronic component 171 and the second electronic component 172 may be provided over the upper side of the upper substrate 130.

Pick-and-place equipment may pick up the first electronic component 171 and the second electronic component 172 and place the first electronic component 171 and the second electronic component 172 on the upper side of the upper substrate 130. The first electronic component interconnects 171a and the second electronic component interconnects 172a may be coupled to the upper substrate upper terminals 132a. In some examples, the first electronic component interconnects 171a and the second electronic component interconnects 172a may be coupled to the upper substrate upper terminals 132a through a reflow, thermal compression, or hybrid bonding process. The first electronic component 171 and the second electronic component 172 may be electrically connected to each other through the upper substrate 130 and the routing component 110. The fine pitch and high density that may be achieved through the redistribution structure conductive structure 115b of the routing component 110 may increase speed and/or decrease resistance, which tends to improve electrical performance. The first electronic component 171 and the second electronic component 172 may also be electrically coupled to the vertical interconnects 140 via the upper substrate conductive structure 132.

In accordance with various examples, the first electronic component 171 and the second electronic component 172 may each comprise an active device, a die, a chip, a package, and/or a passive device. While the first electronic component interconnects 171a and the second electronic component interconnects 172a are shown as being coupled in a face-down, or flip-chip, configuration, there may be examples where the first electronic component interconnects 171a and/or the second electronic component interconnects 172a are coupled in a face-up, or wire bond, configuration. In some examples, the overall thickness of each of the first electronic component 171 and the second electronic component 172 may range from approximately 50 μm to approximately 800 μm, and their respective area may range from approximately 0.5 mm×0.5 mm to approximately 70 mm×70 mm.

FIG. 2G shows a cross-sectional view of the electronic device 100 at a later stage of manufacture. In the example shown in FIG. 2G, the second underfill 162 may be provided between the upper substrate 130 and the first electronic component 171 and between the upper substrate 130 and the second electronic component 172. The upper encapsulant 152 may be provided over and/or covering the first electronic component 171 and the second electronic component 172 and the upper side of the upper substrate 130. The second underfill 162 may contact the lower side of the first electronic component 171, the lower side of the second electronic component 172, and the upper side of the upper substrate 130. In some examples, the second underfill 162 may contact the first electronic component interconnects 171a and/or the second electronic component interconnects 172a. The second underfill 162 may comprise or be referred to as an insulating material or a non-conductive paste and may be free of inorganic fillers. In some examples, the second underfill 162 may comprise or be referred to as a capillary underfill (CUF), a non-conductive paste (NCP), a non-conductive film (NCF), an anisotropic conductive film (ACF), and/or an anisotropic conductive paste (ACP). In some examples, the upper encapsulant 152 may comprise a molded underfill (MUF) and may extend between the upper substrate 130 and the first electronic component 171 and between the upper substrate 130 and the second electronic component 172. In such examples, the second underfill 162 may be considered as part of the upper encapsulant 152.

The upper encapsulant 152 may be provided over and/or covering the first electronic component 171, the second electronic component 172, the upper substrate 130, and the second underfill 162. In some examples, the upper encapsulant 152 may contact one or more sidewalls of the first electronic component 171, one or more sidewalls of the second electronic component 172, an upper side of the upper substrate 130, and one or more sidewalls of the second underfill 162. In some examples, the upper side of the first electronic component 171 and the upper side of the second electronic component 172 may be exposed from and/or coplanar with the upper side of the upper encapsulant 152. Elements, features, materials, and/or manufacturing methods of the upper encapsulant 152 may be similar to, or the same as, those of the lower encapsulant 151.

FIG. 2H shows cross-sectional view of electronic device 100 at later stages of manufacture. FIG. 2HA is an enlarged view of area A in FIG. 2H. In the example shown in FIGS. 2H and 2HA, a third carrier 30 is provided over and/or covering the upper side of the first electronic component 171, the upper side of the second electronic component 172, and the upper side of the upper encapsulant 152. After providing the third carrier 30, the first carrier 10, including inorganic layer 11, may be removed from the lower side of lower encapsulant 151, the lower side of routing component 110, and lower sides of the vertical interconnects 140.

In some examples, the third carrier 30 may comprise a temporary bond layer, similar to temporary bond layer 21 in FIG. 3B. The temporary bond layer may contact the upper side of the first electronic component 171, the upper side of the second electronic component 172, and the upper side of the upper encapsulant 152. Elements, features, and/or materials of the third carrier 30 may be similar to, or the same as, those of the second carrier 20.

In response to removal of the first carrier 10 and the inorganic layer 11, the lower side of the lower encapsulant 151, the lower side of the vertical interconnects 140, and the lower side of the routing component 110 may be exposed. In some examples, the first carrier 10 may be removed by grinding and the inorganic layer 11 may be removed by etching. In some examples, after the first carrier 10 and the inorganic layer 11 are removed, a portion of the lower side of the lower encapsulant 151, the lower side of the vertical interconnects 140, and the lower side of the routing component 110 may be exposed through grinding and/or etching. The routing component inorganic layer 112 of the routing component 110 tends to be easily ground and/or etched, as compared to for example, die attached film. Grinding and/or etching the routing component inorganic layer 112 may allow for easy and/or increased planarization of the lower side of the routing component 110. Better planarization (e.g., decreased unevenness) tends to allow for better redistribution layer formation. Removal of the routing component inorganic layer 112 exposes the lower side of the routing component through-interconnects 114 and/or the routing component lower interconnects 116. In some examples, the routing component inorganic layer 112 may be partially removed, such that a portion of the routing component inorganic layer 112 remains around a lower portion of the routing component through-interconnects 114 and/or the routing component lower interconnects 116.

FIG. 2I shows a cross-sectional view of the electronic device 100 at later stages of manufacture. FIG. 2IA is an enlarged view of portion A of FIG. 2I. In the example shown in FIGS. 2I and 2IA, the lower substrate 120 may be provided over and/or covering the lower side of the lower encapsulant 151, the lower side of the vertical interconnects 140, and the lower side of the routing component 110.

The lower substrate 120 may comprise the lower substrate dielectric structure 121 and the lower substrate conductive structure 122. In accordance with various examples, the lower substrate dielectric structure 121 may comprise or be referred to as one or more dielectrics, dielectric materials, dielectric layers, passivation layers, insulating layers, or protective layers. In some examples, the lower substrate dielectric structure 121 may comprise organic dielectric materials. For example, the lower substrate dielectric structure 121 may comprise an electrically insulating material such as polymer, PI, BCB, PBO, BT, or ABF. In some examples, the lower substrate dielectric structure 121 may be provided by spin coating, spray coating, dip coating, rod coating, printing, oxidation, PVD, CVD, MOCVD, ALD, LPCVD, PECVD, or other processes as known to one of ordinary skill in the art. The lower substrate dielectric structure 121 may maintain the shape of lower substrate 120 and may also structurally support the lower substrate conductive structure 122. The lower substrate dielectric structure 121 may contact and be interleaved with conductive layers and/or structures of the lower substrate conductive structure 122. In some examples, the thicknesses of individual dielectric layers of the lower substrate dielectric structure 121 may range from about 3 μm to about 100 μm.

In accordance with various embodiments, the lower substrate conductive structure 122 may comprise or be referred to as one or more conductors, conductive materials, conductive paths, conductive layers, RDLs, wiring layers, signal distribution elements, traces, vias, pads, or UBM. In some examples, one or more of the conductive layers of the the lower substrate conductive structure 122 may be interleaved with dielectric layers of the lower substrate dielectric structure 121. In some examples, the lower substrate conductive structure 122 may comprise Cu, Al, Ni, Pd, Ti, W, Ti/W, Au, Ag, an alloy, or other suitably conductive material known to one of ordinary skill in the art. In some examples, the lower substrate conductive structure 122 may be provided by sputtering, electroless plating, electrolytic plating, PVD, CVD, MOCVD, ALD, LPCVD, PECVD, or other processes as known to one of ordinary skill in the art. The lower substrate upper terminals 122a of the lower substrate conductive structure 122 may be located at the upper side of the lower substrate dielectric structure 121 and may be coupled to the vertical interconnects 140 and/or the routing component through-interconnects 114. The lower substrate lower terminals 122b of the lower substrate conductive structure 122 may be located at the lower side of the lower substrate dielectric structure 121. In some examples, the thickness of lower substrate 120 may range from approximately 0.5 μm to approximately 50 μm. Elements, features, materials, and/or manufacturing methods of lower substrate 120 may be similar to, or the same as, those of upper substrate 130. In accordance with various examples, the lower substrate dielectric structure 121 and the lower substrate conductive structure 122 may each include any number of layers (i.e., fewer or more layer than the number of layers shown in FIG. 2IA). In some examples, the overall the thickness of lower substrate 120 may range from approximately 0.5 μm to approximately 50 μm.

FIG. 2J shows a cross-sectional view of the electronic device 100 at a later stage of manufacture. In the example shown in FIG. 2J, the lower substrate interconnect structures 125 may be provided on the lower side of lower substrate 120.

The lower substrate interconnect structures 125 may be coupled to the lower substrate conductive structure 122 (e.g., the lower substrate lower terminals 122b) of the lower substrate 120. In some examples, the lower substrate interconnect structures 125 may comprise tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. The lower substrate interconnect structures 125 may be provided through a reflow process after forming a conductive material including solder on the lower substrate conductive structure 122 through a ball drop method. The lower substrate interconnect structures 125 may comprise or be referred to as conductive balls such as solder balls, conductive pillars such as copper pillars, or conductive posts having solder caps provided on copper pillars.

In accordance with various examples, through the above-described processes, electronic modules 100A may be provided in a wafer or panel form. The wafer or panel may then be singulated to provide individual, discrete electronic modules 100A. Singulation may include cutting or sawing along saw streets S and/or through the lower encapsulant 151, the upper encapsulant 152, the lower substrate 120, and/or the upper substrate 130. Through the singulation process, the lateral sides of the lower encapsulant 151, the upper encapsulant 152, the lower substrate 120, and/or the upper substrate 130 may be coplanar. In some examples, the lower substrate interconnect structures 125 may comprise input/output terminals of individual electronic modules 100A.

FIG. 2K shows a cross-sectional view of the electronic device 100 at a later stage of manufacture. In the example shown in FIG. 2K, individual electronic modules 100A may be located on the base substrate 180. In some examples, the first underfill 161 may be provided between the electronic modules 100A and the upper side of the base substrate 180.

The base substrate 180 may comprise the base substrate dielectric structure 181 and the base substrate conductive structure 182. In some examples, the base substrate dielectric structure 181 may comprise or be referred to as one or more stacked dielectric layers. For instance, the one or more dielectric layers may comprise, one or more core layers, polymer layers, pre-preg layers, or solder mask layers stacked on each other. One or more layers or elements of the base substrate conductive structure 182 may be interleaved with one or more layers or elements of the base substrate dielectric structure 181. In some examples, the base substrate dielectric structure 181 may comprise PI, BCB, PBO, resin, ABF, epoxy, or ceramic. In some examples, the thickness of the base substrate dielectric structure 181 may range from approximately 10 μm to 500 μm.

The base substrate conductive structure 182 may comprise one or more conductive layers and may define conductive paths with elements such as traces, pads, vias, wiring patterns, and/or UBM. The base substrate conductive structure 182 may comprise the base substrate upper terminals 182a provided at the upper side of base substrate 180, the base substrate lower terminals 182b provided at the lower side of the base substrate 180. The lower substrate interconnect structures 125 of the electronic modules 100A may be coupled to the base substrate upper terminals 182a of the base substrate 180.

The base substrate conductive structure 182 may be provided in the base substrate dielectric structure 181 and may couple the base substrate upper terminals 182a to the base substrate lower terminals 182b. In some examples, the base substrate conductive structure 182 may comprise copper, iron, nickel, gold, silver, palladium, or tin. The base substrate upper terminals 182a and the base substrate lower terminals 182b may be respectively provided along the upper side of the base substrate 180 and the lower side of the base substrate 180 in a matrix form having rows and/or columns. In some examples, the base substrate upper terminals 182a and the base substrate lower terminals 182b may comprise or be referred to as a substrate land, a conductive land, a substrate pad, a wiring pad, a connection pad, a micro pad, or UBM.

In some examples, the base substrate 180 may comprise a laminate substrate, a ceramic substrate, a rigid substrate, a glass substrate, a printed circuit board, a multilayer substrate, or a molded lead frame. In some examples, the base substrate 180 may comprise a redistribution layer substrate, a buildup substrate, or a coreless substrate. In some example, the base substrate 180 may have an area varying according to the area or number of electronic components 171, 172, 173 included in the electronic module 100A and may have an area of approximately 8 mm×8 mm to approximately 100 mm×100 mm. The base substrate 180 may have a thickness of approximately 0.05 mm to approximately 4 mm.

The base substrate 180 may be electrically connected to the first electronic component, 171, the second electronic component 172, and the third electronic component 173 through the lower substrate interconnect structures 125, the lower substrate 120, the vertical interconnects 140, and the upper substrate 130. The base substrate 180 may also be electrically connected to the first electronic component 171 and the second electronic component 172 through the lower substrate interconnect structures 125, the lower substrate 120, the routing component 110 (e.g., the routing component through-interconnects 114, the routing component redistribution structure 115, and the routing component upper interconnects 119), and the upper substrate 130.

The first underfill 161 may be provided between the upper side of the base substrate 180 and the lower side of the electronic module 100A. The first underfill 161 may contact the upper side of the base substrate 180, sidewalls of the lower substrate interconnect structures 125, and the lower side of the lower substrate 120. The first underfill 161 may prevent or reduce occurrences of the electronic module 100A separating from the base substrate 180 due to physical, thermal, and/or chemical impacts. The first underfill 161 may have elements, features, materials, and/or manufacturing methods that are similar to, or that same as, those of the second underfill 162.

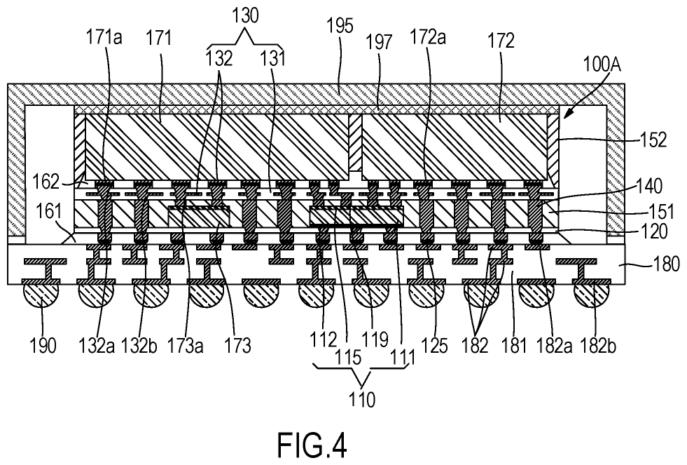

In some examples, a lid 195 may be provided on the upper side of the first electronic component 171, the second electronic component 172, and the upper encapsulant 152. See, e.g., FIG. 4. A thermal interface material (TIM) and/or a backside metal (BSM) 197 may be interposed between the lid 190 and the first electronic component 171 and the second electronic component 172 to facilitate heat transfer and coupling. In some examples, the lid 195 may be coupled to the base substrate 180 (e.g., to the base substrate conductive structure 182).

FIG. 2L shows a cross-sectional view of the electronic device 100 at a later stage of manufacture. In the example shown in FIG. 2L, the base substrate external interconnects 190 may be provided on the lower side of the base substrate 180. The base substrate external interconnects 190 may be coupled to the base substrate lower terminals 182b. The base substrate external interconnects 190 may be ball-grid arrayed or land-grid-arrayed on the base substrate 180. In some examples, the size of the base substrate external interconnects 190 may range from may range from approximately 10 μm to approximately 600 μm. In some examples, the base substrate external interconnects 190 may be referred to as external input/output terminals of the electronic device 100. The base substrate external interconnects 190 may have elements, features, materials, and/or manufacturing methods that are similar to, or the same as those of the lower substrate interconnect structures 125.

In accordance with various examples, the routing component 110 may transmit signals between the first electronic component 171 and the second electronic component 172 and may transmit signals and power between the first electronic component 171, the second electronic component 172, and the base substrate 180. Since the routing component 110 may transmit signals via the fine conductive pattern provided in the routing component redistribution structure 115, a decrease in resistance due to decreased connection distance may be achieved, thereby improving signal transmission characteristics. Bonding the routing component 110 to the first carrier 10 via the inorganic layer 11 and the routing component inorganic layer 112 may prevent or reduce shifting of the routing component 110, thereby reducing or preventing misalignment issues. Additionally, replacing an adhesive in favor of the routing component inorganic layer 112 for attaching the routing component 110 to the first carrier 10 eliminates the issues (e.g., component shifting and/or tilting) and/or damage that may be caused by voids in the adhesive.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. A method of manufacturing an electronic device, the method comprising:
providing vertical interconnects over an upper side of a first carrier;
bonding a routing component inorganic layer on a lower side of a routing component to an inorganic layer on the upper side of the first carrier;
encapsulating the vertical interconnects and the routing component in a lower encapsulant;
providing an upper substrate to an upper side of the lower encapsulant such that a conductive structure of the upper substrate is coupled to upper sides of the vertical interconnects and to an upper side of the routing component;
coupling a first electronic component and a second electronic component to an upper side of the upper substrate;
providing a second carrier over the first electronic component and the second electronic component;
removing the first carrier from the routing component and the vertical interconnects; and
providing a lower substrate to a lower side of the lower encapsulant such that a conductive structure of the lower substrate is coupled to lower sides of the vertical interconnects.

2. The method of claim 1, wherein bonding comprises forming a covalent bond between the routing component inorganic layer and the inorganic layer on the upper side of the first carrier.

3. The method of claim 1, wherein bonding comprises forming hydroxyl (OH) groups on the lower side of the routing component inorganic layer and the upper side of the inorganic layer.

4. The method of claim 1, wherein bonding comprises:
generating hydrogen (H) on the lower side of the routing component inorganic layer and the upper side of the inorganic layer through plasma treatment;
binding oxygen (O) particles separated during plasma treatment to the hydrogen (H) generated on the lower side of the routing component inorganic layer and the upper side of the inorganic layer; and
inducing hydroxyl (OH) groups on the lower side of the routing component inorganic layer and the upper side of the inorganic layer.

5. The method of claim 1, wherein bonding occurs at temperatures ranging from approximately 25° C. to approximately 400° C.

6. The method of claim 1, comprising encapsulating the first electronic component and the second electronic component in an upper encapsulant prior to providing the second carrier.

7. The method of claim 1, wherein providing the upper substrate comprises coupling the conductive structure of the upper substrate to a routing component redistribution structure at the upper side of the routing component.

8. The method of claim 1, wherein providing the lower substrate comprises coupling the conductive structure of the lower substrate to lower sides of routing component through-interconnects that extend through a routing component die.

9. The method of claim 1, comprising:
coupling a lower side of the lower substrate to an upper side of a base substrate; and
providing external interconnects to a lower side of the base substrate.

10. A method of manufacturing an electronic device, the method comprising:
providing a lower substrate comprising an upper side and a lower side;
providing a routing component on the upper side of the lower substrate, wherein the routing component comprises a routing component die, a routing component redistribution structure on an upper side of the routing component die, and a routing component inorganic layer along a lower side of the routing component die, and wherein a lower side of the routing component inorganic layer contacts the upper side of the lower substrate;
providing vertical interconnects on the upper side of the lower substrate;
providing a lower encapsulant that encapsulates the vertical interconnects and the routing component;
providing an upper substrate over the lower encapsulant such that a lower side of the upper substrate is coupled to an upper side of the routing component redistribution structure; and
providing a first electronic component and a second electronic component coupled to an upper side of the upper substrate such that the first electronic component is electrically coupled to the second electronic component via the upper substrate and the routing component redistribution structure.

11. The method of claim 10, comprising providing routing component through-interconnects that extend through the routing component die and couple the routing component redistribution structure to the lower substrate.

12. The method of claim 10, comprising providing an upper encapsulant that encapsulates the first electronic component and the second electronic component.

13. The method of claim 10, comprising providing an underfill between a lower side of the first electronic component and the upper side of the upper substrate.

14. The method of claim 10, comprising:
providing a base substrate comprising an upper side and a lower side;
providing lower substrate interconnect structures that couple a lower side of the lower substrate to the upper side of the base substrate; and
providing external terminals coupled to the lower side of the base substrate.

15. The method of of claim 10, providing a third electronic component coupled to the lower side of the upper substrate.

16. An electronic device, comprising:
a lower substrate comprising an upper side and a lower side;
an upper substrate comprising an upper side and a lower side;
vertical interconnects that couple the upper side of the lower substrate to the lower side of the upper substrate;
a routing component comprising a routing component die, a routing component redistribution structure on an upper side of the routing component die, and a routing component inorganic layer along a lower side of the routing component die, wherein an upper side of the routing component redistribution structure is coupled to the lower side of the upper substrate, and wherein a lower side of the routing component inorganic layer contacts the upper side of the lower substrate;
a lower encapsulant that encapsulates the routing component and the vertical interconnects;
a first electronic component coupled to the upper side of the upper substrate; and
a second electronic component coupled to the upper side of the upper substrate, wherein the second electronic component is electrically coupled to the first electronic component via the upper substrate and the routing component redistribution structure.

17. The electronic device of claim 16, wherein:
the routing component comprises routing component through-interconnects; and
the routing component through-interconnects extend through the routing component die and couple the routing component redistribution structure to the upper side of the lower substrate.

18. The electronic device of claim 16, comprising an upper encapsulant that encapsulates the first electronic component and the second electronic component.

19. The electronic device of claim 16, comprising:
a third electronic component coupled to the lower side of the upper substrate; and
wherein the lower encapsulant encapsulates the third electronic component.

20. The electronic device of claim 16, comprising the lower side of the lower encapsulant is coplanar with the lower side of the routing component inorganic layer.
